(19) United States
(12) Patent Application Publication
(10) Pub. No.: US 2025/0205826 A1
(43) Pub. Date: Jun. 26, 2025

(54) SEPARATION START POINT FORMING METHOD AND SEPARATION METHOD

(71) Applicant: DISCO CORPORATION, Tokyo (JP)

(72) Inventor: Kazuya HIRATA, Tokyo (JP)

(21) Appl. No.: 18/968,045

(22) Filed: Dec. 4, 2024

(30) Foreign Application Priority Data
Dec. 20, 2023 (JP) 2023-214824

(51) Int. Cl. B23K 26/53; B23K 26/08; B23K 103/00; B28D 5/00; H01L 21/268

(52) U.S. Cl. CPC B23K 26/53; B28D 5/0011; H01L 21/268; B23K 26/08; B23K 2103/56

(57) ABSTRACT

A method is of forming, inside a workpiece having first and second surfaces, a separation start point for separating the workpiece into the first and second surface sides. The method includes: holding the workpiece to expose the first surface; setting a specific region on the first surface; and repeating processing feed and indexing feed to form modified portions inside the workpiece and form a separation start point including the modified portions. The processing feed is of relatively moving a condensing point of a laser beam in a processing feed direction with respect to the workpiece while emitting the laser beam toward the first surface with the condensing point positioned inside the workpiece to form a strip-shaped modified portion inside the workpiece. The indexing feed is being of relatively moving the condensing point in an indexing feed direction, orthogonal to the processing feed direction, with respect to the workpiece.

### CROSS-REFERENCE TO RELATED APPLICATION(S)

The present application claims priority to and incorporates by reference the entire contents of Japanese Patent Application No. 2023-214824 filed in Japan on Dec. 20, 2023.

### BACKGROUND

The present disclosure relates to a separation start point forming method of forming a separation start point for separating a workpiece into a first surface side and a second surface side, and a separation method.

For example, there is proposed a method in which an ingot or a wafer made of silicon carbide (SiC) single crystal or silicon is irradiated with a laser beam to form a separation start point inside, and then the wafer is separated (see, for example, JP 2013-049161 A and JP 2011-060862 A).

Meanwhile, in the SiC single crystal, a facet region and a non-facet region having different growth modes are formed in the growth process. The facet region has a higher energy absorption rate than the non-facet region. Therefore, in the facet region, the intensity of the laser beam reaching a condensing point is weaker than that in the non-facet region, and there is a possibility that a sufficient separation layer is not formed in the facet region so that separation failure occurs, and thus improvement is desired.

### SUMMARY

A separation start point forming method according to one aspect of the present disclosure is of forming, inside a workpiece that has a first surface and a second surface at a back of the first surface, a separation start point for separating the workpiece into the first surface side and the second surface side. The separation start point forming method includes: holding the workpiece by a holding unit to expose the first surface; setting a specific region on the first surface of the workpiece before or after the holding; and after the holding and the setting, repeating processing feed and indexing feed to form a plurality of modified portions inside the workpiece and form a separation start point including the plurality of modified portions inside the workpiece, the processing feed being of relatively moving a condensing point of a laser beam in a processing feed direction with respect to the workpiece while emitting the laser beam toward the first surface with the condensing point positioned inside the workpiece to form a strip-shaped modified portion inside the workpiece, the indexing feed being of relatively moving the condensing point in an indexing feed direction, orthogonal to the processing feed direction, with respect to the workpiece after the processing feed. In the repeating, an interval between the modified portions adjacent to each other in the specific region is set to be narrower than an interval between the modified portions adjacent to each other outside the specific region.

A separation method according to another aspect of the present disclosure is of separating a workpiece that has a first surface and a second surface at a back of the first surface into the first surface side and the second surface side. The separation method includes: holding the workpiece by a holding unit to expose the first surface; setting a specific region on the first surface of the workpiece before or after the holding; after the holding and the setting, repeating processing feed and indexing feed to form a plurality of modified portions inside the workpiece and form a separation start point including the plurality of modified portions inside the workpiece, the processing feed being of relatively moving a condensing point of a laser beam in a processing feed direction with respect to the workpiece while emitting the laser beam toward the first surface with the condensing point positioned inside the workpiece to form a strip-shaped modified portion inside the workpiece, the indexing feed being of relatively moving the condensing point in an indexing feed direction, orthogonal to the processing feed direction, with respect to the workpiece after the processing feed; and after the repeating, separating the workpiece from the separation start point into the first surface side and the second surface side. In the repeating, an interval between the modified portions adjacent to each other in the specific region is set to be narrower than an interval between the modified portions adjacent to each other outside the specific region.

### BRIEF DESCRIPTION OF THE DRAWINGS

FIG. 1 is a perspective view illustrating a configuration example of a separation apparatus that performs a separation start point forming method and a separation method according to a first embodiment;

FIG. 2 is a plan view of an ingot to be processed by the separation start point forming method and the separation method according to the first embodiment;

FIG. 3 is a side view of the ingot illustrated in FIG. 2;

FIG. 4 is a perspective view of a wafer manufactured by peeling a portion of the ingot illustrated in FIG. 2;

FIG. 5 is a diagram schematically illustrating a configuration of a facet region detection unit of the separation apparatus illustrated in FIG. 1;

FIG. 6 is a flowchart illustrating a flow of the separation method according to the first embodiment;

FIG. 7 is a perspective view schematically illustrating a specific region setting step of the separation method illustrated in FIG. 6;

FIG. 8 is a plan view illustrating an example of a facet region of an SiC ingot illustrated in FIG. 7;

FIG. 9 is a view illustrating an example of XY coordinates of an outer edge of the facet region illustrated in FIG. 8;

FIG. 10 is a perspective view schematically illustrating a laser processing step of the separation method illustrated in FIG. 6;

FIG. 11 is a cross-sectional view schematically illustrating a surface layer of a first surface of an ingot illustrated in FIG. 10 on which a peeling layer is formed;

FIG. 12 is a plan view schematically illustrating the ingot after a first sub-step of the laser processing step illustrated in FIG. 10;

FIG. 13 is a plan view schematically illustrating a path of laser beam irradiation in a second sub-step of the laser processing step illustrated in FIG. 10;

FIG. 14 is a perspective view schematically illustrating a separation step of the separation method illustrated in FIG. 6;

FIG. 15 is a plan view schematically illustrating an ingot after a first sub-step of a laser processing step of a separation start point forming method and a separation method according to a first modification of the first embodiment;

FIG. 16 is a plan view schematically illustrating a path of laser beam irradiation in a second sub-step of the laser processing step of the separation start point forming method and the separation method according to the first modification of the first embodiment; and

FIG. 17 is a plan view schematically illustrating a path of laser beam irradiation in a first sub-step and a second sub-step of a laser processing step of a separation start point forming method and a separation method according to a second modification of the first embodiment.

### DETAILED DESCRIPTION OF THE PREFERRED EMBODIMENTS

Modes (embodiments) for carrying out the present disclosure will be described in detail with reference to the drawings. The present invention is not limited by the contents described in the following embodiment. In addition, components to be described below include those that can be easily assumed by those skilled in the art and those that are substantially the same. Furthermore, configurations described below can be appropriately combined. In addition, various omissions, substitutions, or changes of the configurations can be made within a scope not departing from the gist of the present invention.

### First Embodiment

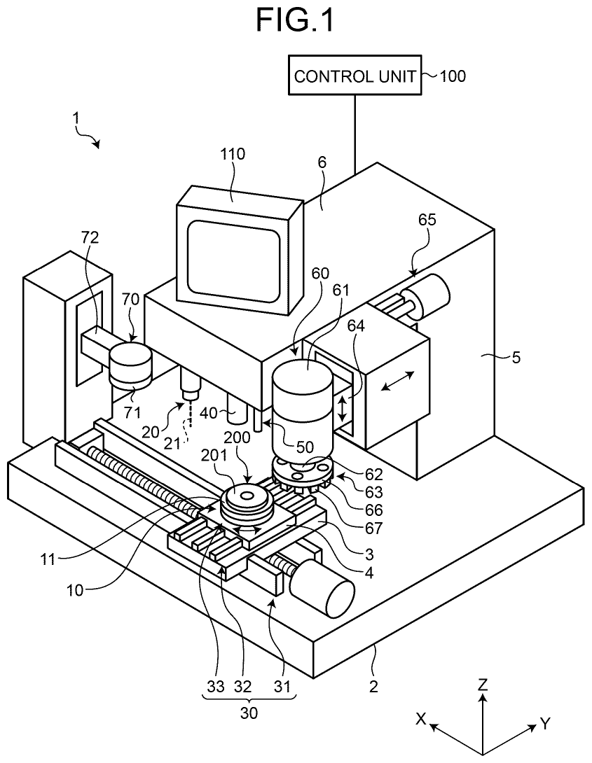

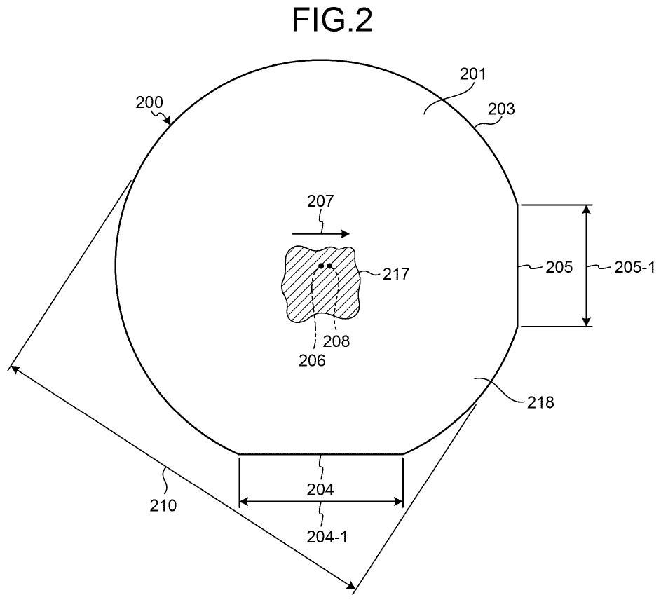

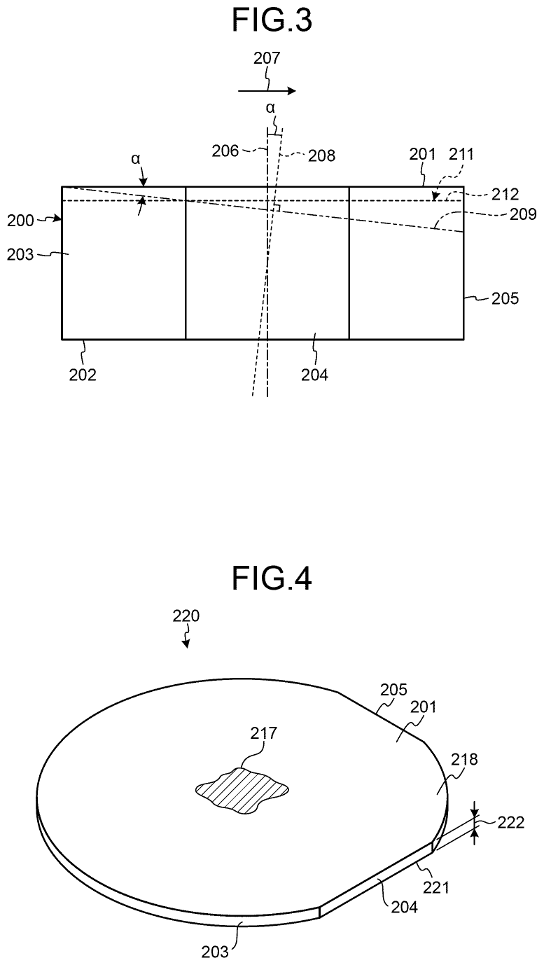

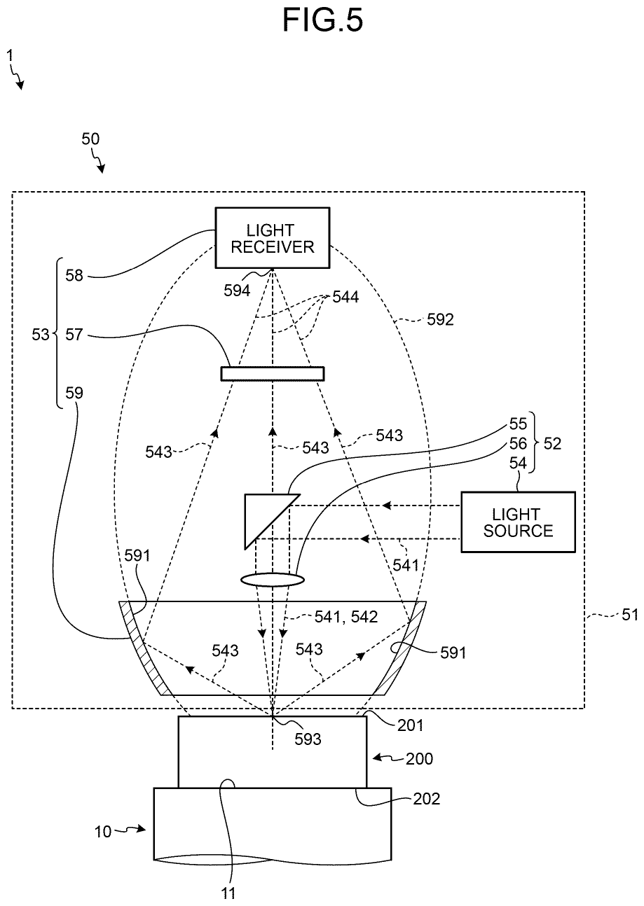

A separation start point forming method and a separation method according to a first embodiment of the present disclosure will be described with reference to the drawings. FIG. 1 is a perspective view illustrating a configuration example of a separation apparatus that performs the separation start point forming method and the separation method according to the first embodiment. FIG. 2 is a plan view of an ingot to be processed by the separation start point forming method and the separation method according to the first embodiment. FIG. 3 is a side view of the ingot illustrated in FIG. 2. FIG. 4 is a perspective view of a wafer manufactured by peeling a portion of the ingot illustrated in FIG. 2. FIG. 5 is a diagram schematically illustrating a configuration of a facet region detection unit of the separation apparatus illustrated in FIG. 1.

### Ingot

The separation start point forming method and the separation method according to the first embodiment are methods of performing laser processing on an ingot 200 (corresponding to a workpiece) illustrated in FIG. 2 and the like by a separation apparatus 1 illustrated in FIG. 1. The ingot 200 illustrated in FIGS. 2 and 3 to be processed by the separation start point forming method and the separation method according to the first embodiment is made of silicon carbide (Sic) and formed in a cylindrical shape as a whole in the first embodiment. In the first embodiment, the ingot 200 is a hexagonal single crystal ingot.

As illustrated in FIGS. 2 and 3, the ingot 200 has a first surface 201 that is an upper surface formed in a circular shape, a second surface 202 formed in a circular shape on the back side of the first surface 201, and a peripheral surface 203 continuous with an outer edge of the first surface 201 and an outer edge of the second surface 202. In addition, the ingot 200 has, on the peripheral surface 203, a first orientation flat 204 indicating a crystal orientation of the ingot 200 and a second orientation flat 205 that is orthogonal to the first orientation flat 204 and indicates a crystal orientation of the ingot 200. The orientation flats 204 and 205 are flat planes each forming a straight line in a plan view of the ingot 200. A length 204-1 of the first orientation flat 204 is longer than a length 205-1 of the second orientation flat 205.

In addition, the ingot 200 has a C-axis 208, inclined at an off-angle a in an inclination direction 207 toward the second orientation flat 205 with respect to a perpendicular line 206 of the first surface 201, and a c-plane 209 orthogonal to the C-axis 208. The c-plane 209 is inclined at the off-angle a with respect to the first surface 201 of the ingot 200. The inclination direction 207 from the perpendicular line 206 of the C-axis 208 is orthogonal to an extending direction of the second orientation flat 205 and parallel to the first orientation flat 204.

An infinite number of the c-planes 209 are set in the ingot 200 at the molecular level of the ingot 200. The off-angle a is set to 1°, 4°, or 6° in the first embodiment, but the off-angle a can be freely set in a range of, for example, 1° to 6° to manufacture the ingot 200 in the present disclosure.

In addition, the ingot 200 is generally doped with an impurity such as nitrogen in order to impart conductivity. For this reason, in the ingot 200, a region 217 (which corresponds to a specific region and is hereinafter referred to as a facet region and indicated by parallel oblique lines in FIG. 2) called facet and having a different crystal structure may be formed in the growth process of the SiC single crystal without being uniformly doped with such an impurity. An impurity concentration of the facet region 217 is higher than that of a region 218 (hereinafter referred to as a non-facet region and indicated by a white background in FIG. 2) outside the facet region 217. In this manner, the facet region 217 is different in impurity concentration from the non-facet region 218. The facet region 217 has a higher refractive index and a higher energy absorption rate than the non-facet region 218.

In addition, in the ingot 200, the first surface 201 is subjected to grinding processing by a grinder or the like to form the first surface 201 into a mirror surface. A portion of the ingot 200 on the first surface 201 side is peeled off, and the peeled portion is generated as a wafer 220 illustrated in FIG. 4. In addition, there are a plurality of types of the ingots 200 having different diameters 210.

The wafer 220 illustrated in FIG. 4 is manufactured by peeling a portion including the first surface 201 of the ingot 200 as the wafer 220 and subjecting a peeling surface 221 peeled from the ingot 200 to grinding processing, polishing processing, or the like. After the wafer 220 is peeled from the ingot 200, a device is formed on the surface. The device is a metal-oxide-semiconductor field-effect transistor (MOSFET), micro electro mechanical systems (MEMS), or a Schottky barrier diode (SBD) in the first embodiment, but the device is not limited to the MOSFET, the MEMS, and the SBD in the present disclosure. Note that the same portions as those of the ingot 200 of the wafer 220 are denoted by the same reference signs, and the description thereof is omitted.

In the ingot 200 illustrated in FIGS. 2 and 3, a peeling layer 211 (corresponding to a separation start point) illustrated in FIG. 3 is formed by the separation apparatus 1 illustrated in FIG. 1, and then a portion of the ingot, that is, the wafer 220 to be generated is separated and peeled from the peeling layer 211 as a start point. In addition, in the ingot 200, a peeling surface 212 from which the wafer 220 has been peeled off is formed into a mirror surface by grinding or the like, the peeling surface 212 is formed as the first surface 201, and the peeling layer 211 is formed again, and the wafer 220 is peeled off. In this manner, a thickness of the ingot 200 is thinned as the wafer 220 is peeled off, the peeling layer 211 is formed and the wafer 220 is peeled off until the thickness reaches a predetermined thickness.

Note that a boundary between the facet region 217 and the non-facet region 218 is illustrated in FIGS. 2 and 4, but this boundary line is an imaginary line and does not exist in the actual ingot 200. Note that the material of the ingot 200 is not limited to SiC, and may be LiTaO₃ (lithium tantalate: LT), GaN (gallium nitride), or silicon. In addition, one or both of the first orientation flat 204 and the second orientation flat 205 are not necessarily provided on the peripheral surface of the ingot 200.

### Separation Apparatus

The separation apparatus 1 illustrated in FIG. 1 is an apparatus that separates and peels a portion, that is, the wafer 220 to be generated from the peeling layer 211 illustrated in FIG. 3 as a start point after the peeling layer 211 is formed in the ingot 200 illustrated in FIGS. 2 and 3, that is, an apparatus that forms the peeling layer 211 for separating the ingot 200 into the first surface 201 side and the second surface 202 side inside the ingot 200 and separates the ingot 200 into the first surface 201 side and the second surface 202 side from the peeling layer 211 as the start point.

As illustrated in FIG. 1, the separation apparatus 1 includes a holding unit 10 that holds the ingot 200 on a holding surface 11, a laser processing unit 20, an imaging unit 40, a facet region detection unit 50, a grinding unit 60, a separation unit 70, and a control unit 100. In addition, the separation apparatus 1 includes a movement unit 30 that relatively moves the holding unit 10, the laser processing unit 20, the imaging unit 40, the facet region detection unit 50, the grinding unit 60, and the separation unit 70 in an X-axis direction parallel to the horizontal direction and a Y-axis direction parallel to the horizontal direction and orthogonal to the X-axis direction.

Note that the X-axis direction is a so-called processing feed direction in which processing feed of the holding unit 10 is performed when the separation apparatus 1 performs laser processing on the ingot 200. The Y-axis direction is orthogonal to the X-axis direction, and is a so-called indexing feed direction in which indexing feed of the holding unit 10 is performed when the separation apparatus 1 performs laser processing on the ingot 200.

The movement unit 30 includes an X-axis movement unit 31 that moves the holding unit 10 in the X-axis direction, a Y-axis movement unit 32 that moves the holding unit 10 in the Y-axis direction, and a rotational movement unit 33 that rotates the holding unit 10 about an axis parallel to a Z-axis direction.

The X-axis movement unit 31 is a unit that performs relative processing feed of the holding unit 10, the laser processing unit 20, the imaging unit 40, the facet region detection unit 50, the grinding unit 60, and the separation unit 70. In the first embodiment, the X-axis movement unit 31 is installed on an apparatus body 2 of the separation apparatus 1. The X-axis movement unit 31 supports a moving plate 3 supporting the Y-axis movement unit 32 so as to be movable in the X-axis direction.

The Y-axis movement unit 32 is a unit that performs relative indexing feed of the holding unit 10, the laser processing unit 20, the imaging unit 40, the facet region detection unit 50, the grinding unit 60, and the separation unit 70. The Y-axis movement unit 32 is installed on the moving plate 3. The Y-axis movement unit 32 supports a second moving plate 4 that supports the rotational movement unit 33 that rotates the holding unit 10 about the axis parallel to the Z-axis direction so as to be movable in the Y-axis direction.

The rotational movement unit 33 is installed on the second moving plate 4 and supports the holding unit 10. The X-axis movement unit 31 and the Y-axis movement unit 32 each include a known ball screw provided so as to be rotatable about an axis, a known pulse motor that rotates the ball screw about the axis, and a known guide rail that supports the moving plates 3 and 4 so as to be movable in the X-axis direction or the Y-axis direction. The rotational movement unit 33 includes a motor that rotates the holding unit 10 about the axis, and the like.

In addition, the separation apparatus 1 includes an X-axis direction position detection unit (not illustrated) for detecting an X-axis direction position of the holding unit 10, a Y-axis direction position detection unit (not illustrated) for detecting a Y-axis direction position of the holding unit 10, and a Z-axis direction position detection unit (not illustrated) for detecting a Z-axis direction position of a condensing lens included in the laser processing unit 20. Each of the position detection units outputs a detection result to the control unit 100.

Note that, in the first embodiment, the X-axis direction position and the Y-axis direction of the holding unit 10 of the separation apparatus 1 are determined based on a predetermined reference position (not illustrated). In the first embodiment, the X-axis direction position and the Y-axis direction position are determined by distances from the reference position in the X-axis direction and the Y-axis direction. In the first embodiment, XY coordinates (coordinates indicated by the distance in the X-axis direction from the reference position indicating the X-axis direction position and the distance in the Y-axis direction from the reference position indicating the Y-axis direction position) represented by the X-axis direction and the Y-axis direction of the separation apparatus 1 can indicate any positions in the X-axis direction and the Y-axis direction of the ingot 200 held on the holding surface 11 of the holding unit 10.

The holding unit 10 is installed on the rotational movement unit 33 of the movement unit 30, and holds the ingot 200 on the holding surface 11 parallel to the horizontal direction. The holding unit 10 has a disk shape, and the holding surface 11 holding the second surface 202 of the ingot 200 is made of porous ceramic or the like. In addition, the holding unit 10 is provided to be movable in the X-axis direction by the X-axis movement unit 31 over the lower side of the separation unit 70, the lower side of the laser processing unit 20, the lower side of the imaging unit 40, the lower side of the facet region detection unit 50, and the lower side of the grinding unit 60, and is provided to be rotatable about the axis parallel to the Z-axis direction by the rotational movement unit 33.

In the holding unit 10, the holding surface 11 is connected to a vacuum suction source (not illustrated) and is sucked by the vacuum suction source to suck and hold the second surface 202 of the ingot 200 placed on the holding surface 11.

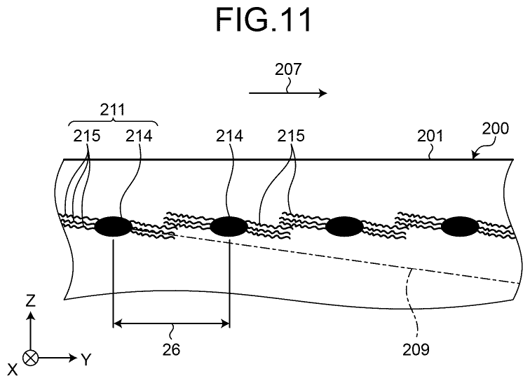

The laser processing unit 20 positions a condensing point of a pulsed laser beam 21 having a wavelength having transmissibility with respect to the ingot 200 in the ingot 200 held by the holding unit 10 at a depth corresponding to a thickness 222 of the wafer 220 to be generated from the first surface 201 of the ingot 200, and irradiates the ingot 200 with the laser beam 21 to form the peeling layer 211 in which SiC is separated into Si and C and a crack 215 (illustrated in FIG. 11) extends along the c-plane 209.

Note that, when the ingot 200 is irradiated with the pulsed laser beam 21 having the wavelength having transmissibility with respect to the ingot 200 while being moved along the second orientation flat 205 relative to the laser beam 21, as illustrated in FIG. 11, SiC is separated into Si (silicon) and C (carbon) by the irradiation of the pulsed laser beam 21, and a modified portion 214 in which the pulsed laser beam 21 irradiated next is absorbed by C formed previously, and SiC is separated into Si and C in a chain manner is formed inside the ingot 200 along the second orientation flat 205, and the crack 215 extending from the modified portion 214 along the c-plane 209 is generated. Thus, when the ingot 200 is irradiated with the pulsed laser beam 21 having the wavelength having transmissibility, the laser processing unit 20 forms the peeling layer 211, which includes the modified portion 214 and the crack 215 formed from the modified portion 214 along the c-plane 209, in the ingot 200.

In the first embodiment, as illustrated in FIG. 1, the laser processing unit 20 is supported by a distal end of a support column 6 whose proximal end is supported by an upright column 5 erected from the apparatus body 2. The laser processing unit 20 includes an oscillator that emits the pulsed laser beam 21 for processing the ingot 200, and a concentrator that condenses the laser beam 21 emitted from the oscillator on the ingot 200 held on the holding surface 11 of the holding unit 10 to form the peeling layer 211.

The concentrator includes a condensing lens (not illustrated) disposed at a position opposing the holding surface 11 of the holding unit 10 in the Z-axis direction. The condensing lens transmits the laser beam 21 oscillated from the oscillator and condenses the laser beam 21 on the condensing point. In addition, in the first embodiment, the concentrator is provided to be movable in the Z-axis direction by a condensing point movement unit (not illustrated).

The imaging unit 40 includes a plurality of imaging elements capturing an image of the ingot 200 held by the holding unit 10. The imaging element is, for example, a charge-coupled device (CCD) imaging element or a complementary MOS (CMOS) imaging element. The imaging unit 40 captures the image of the ingot 200 held on the holding surface 11 of the holding unit 10, acquires the image for performing alignment to align the ingot 200 with the laser processing unit 20, and outputs the acquired image to the control unit 100. In the first embodiment, the imaging unit 40 is supported by the distal end of the support column 6 and is disposed at a position aligned with the condensing lens of the laser processing unit 20 in the X-axis direction.

The facet region detection unit 50 irradiates the ingot 200 with inspection light 542 having a predetermined wavelength from the first surface 201 of the ingot 200 to detect the luminance of SiC-specific fluorescence 543.

As illustrated in FIG. 5, the facet region detection unit 50 includes a case 51 supported by the distal end of the support column 6, an inspection light irradiator 52, and a light receiver 53. The case 51 is formed in a box shape that blocks light having a wavelength of a first wavelength range (for example, 750 nm) or more and has an opening provided on the lower side, and is supported by the distal end of the support column 6. The case 51 is disposed at a position where the opening is aligned in the X-axis direction with the condensing lens of the laser processing unit 20 and the imaging unit 40.

The inspection light irradiator 52 irradiates the first surface 201 of the ingot 200 held by the holding unit 10 with the inspection light 542. The inspection light irradiator 52 includes a light source 54 that oscillates excitation light 541 having a low output (for example, 0.1 W) to such an extent that laser processing is not performed on the ingot 200, a dichroic mirror 55 that reflects the inspection light 542, which is light having a wavelength in a second wavelength range (for example, 365 nm to 375 nm) to be absorbed by the ingot 200 out of the excitation light 541 oscillated from the light source 54, and transmits light having a wavelength outside the second wavelength range, and a condensing lens 56 that condenses the inspection light 542 reflected by the dichroic mirror 55 to irradiate the first surface 201 of the ingot 200.

The light source 54, the dichroic mirror 55, and the condensing lens 56 are disposed in the case 51. The light source 54 includes, for example, a GaN-based light emitting element, and irradiates the dichroic mirror 55 with the excitation light 541 including light having a wavelength (for example, 365 nm) to be absorbed by the ingot 200.

Note that, when the inspection light 542 in the second wavelength range is emitted, the ingot 200 absorbs the inspection light 542 and is excited by the inspection light 542 to generate the fluorescence 543. For example, when the wavelength of the inspection light 542 is 365 nm, the inspection light 542 enters from the first surface 201 of the ingot 200 to a depth of about 10 μm. Then, the fluorescence 543 is generated from a plate-like region having a thickness of about 10 μm on the first surface 201 side of the ingot 200.

The light receiver 53 condenses and receives the fluorescence 543 generated when the ingot 200 is excited by the inspection light 542. The light receiver 53 includes an annular elliptical mirror 59, which is disposed in the case 51 and has an inner reflecting surface 591, a filter 57 disposed in the case 51, and a light receiving unit 58.

The elliptical mirror 59 is disposed closer to the holding surface 11 of the holding unit 10 than the condensing lens 56, and the reflecting surface 591 corresponds to a part of a curved surface of a spheroid obtained by rotating an ellipse 592 having a major axis extending in the vertical direction and a minor axis extending in the horizontal direction about the major axis.

The elliptical mirror 59 has two focal points 593 and 594, and condenses light generated from one (for example, the focal point 593) thereof to the other (for example, the focal point 594). One focal point 593 of the elliptical mirror 59 is designed to substantially match a focal point of the condensing lens 56. The other focal point 594 of the elliptical mirror 59 is set to the light receiving unit 58. The elliptical mirror 59 causes the fluorescence 543, generated by the ingot 200 held by the holding unit 10, to be reflected on the reflecting surface 591, transmitted through the filter 57, and then received by the light receiving unit 58.

The filter 57 includes an IR filter that is disposed between the condensing lens 56 and the light receiving unit 58, transmits light 544 having a wavelength in the first wavelength range out of the fluorescence 543, generated by the ingot 200 and transmitted through the condensing lens 56, and blocks light 544 having a wavelength outside the first wavelength range.

The light receiving unit 58 receives the light 544 having the wavelength in the first wavelength range transmitted by the filter 57 out of the fluorescence 543 generated from the ingot 200 and transmitted through the condensing lens 56, generates a signal indicating the luminance of the received light 544, and outputs the generated signal to the control unit 100. Here, the luminance decreases in a region of the ingot 200 having a higher impurity concentration at a position irradiated with the inspection light 542. That is, the luminance of the light 544 from the facet region 217 is less than the luminance of the light 544 from the non-facet region 218.

In addition, although not illustrated, the facet region detection unit 50 includes a condensing point position adjusting unit that lifts and lowers the case 51 to adjust a position of a condensing point of the inspection light 542 in the Z-axis direction, and the condensing point position adjusting unit includes, for example, a ball screw connected to the case 51 and extending in the Z-axis direction, a motor that rotates the ball screw, and the like.

The grinding unit 60 includes a spindle motor 61, a spindle 62 rotated about an axis parallel to the Z-axis direction by the spindle motor 61, a grinding wheel 63 attached to a lower end of the spindle 62, a grinding feed unit 64 that lifts and lowers the spindle motor 61, the spindle 62, and the grinding wheel 63 in the Z-axis direction, and a Y-axis direction position changing unit 65 that is installed on the support column 6 and changes positions of the spindle motor 61, the spindle 62, and the grinding wheel 63 in the Y-axis direction for the grinding feed unit 64.

The grinding wheel 63 is disposed at a position aligned in the X-axis direction with the condensing lens of the laser processing unit 20, the imaging unit 40, and the facet region detection unit 50. The grinding wheel 63 includes an annular wheel base 66 attached to the lower end of the spindle 62 and a plurality of abrasive members 67 annularly disposed on a lower surface of the wheel base 66. That is, the grinding wheel 63 fixes the plurality of abrasive members 67 at equal intervals in the circumferential direction of the wheel base 66.

The abrasive member 67 is configured as one so-called segment abrasive formed as one lump by mixing abrasive grains such as diamond or cubic boron nitride (CBN) with a bonding material (also referred to as a bonding material) formed of metal, ceramic, resin, or the like.

The separation unit 70 includes a disk-shaped holding plate 71 that sucks and holds the first surface 201 of the ingot 200 held by the holding unit 10, an ultrasonic vibration applying unit (not illustrated) that applies ultrasonic vibration to the holding plate 71, and a lifting unit 72 that lifts and lowers the holding plate 71 in the Z-axis direction. The holding plate 71 is disposed at a position aligned in the X-axis direction with the condensing lens of the laser processing unit 20, the imaging unit 40, the facet region detection unit 50, and the grinding wheel 63 of the grinding unit 60. The lifting unit 72 is installed on an upright column 7 erected from the apparatus body 2.

The control unit 100 controls each of the above-described components of the separation apparatus 1 to cause the separation apparatus 1 to perform a processing operation on the ingot 200. Note that the control unit 100 is a computer that includes an arithmetic processing device including a microprocessor such as a central processing unit (CPU), a storage device including a memory such as a read only memory (ROM) or a random access memory (RAM), and an input/output interface device. The arithmetic processing device of the control unit 100 performs arithmetic processing according to a computer program stored in the storage device, and outputs a control signal for controlling the separation apparatus 1 to the above-described components of the separation apparatus 1 via the input/output interface device, thereby implementing functions of the control unit 100.

In addition, the control unit 100 is connected to a display unit 110 including a liquid crystal display device or the like that displays a state of the processing operation, an image, or the like, and an input unit (not illustrated) used when an operator registers processing content information or the like. The input unit includes at least one of a touch panel provided on the display unit 110 and an external input device such as a keyboard.

### Separation Method

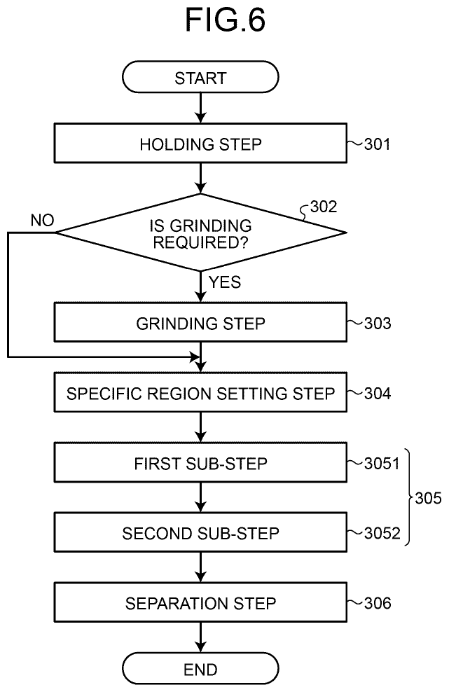

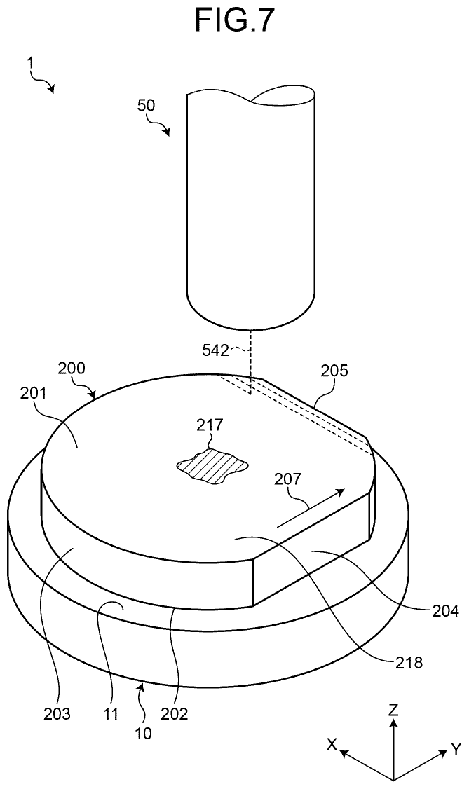

Next, the separation method according to the first embodiment will be described. A processing method according to the first embodiment is also a processing operation performed on the ingot 200 by the separation apparatus 1 having the above-described configuration. FIG. 6 is a flowchart illustrating a flow of the separation method according to the first embodiment.

The separation method according to the first embodiment is a method of separating and peeling a portion, that is, the wafer 220 to be generated, from the peeling layer 211 as a start point after the peeling layer 211 is formed in the ingot 200, that is, a method of forming the peeling layer 211 for separating the ingot 200 into the first surface 201 side and the second surface 202 side inside the ingot 200 and separating the ingot 200 into the first surface 201 side and the second surface 202 side from the peeling layer 211 as the start point. As illustrated in FIG. 6, the separation method includes a holding step 301, a specific region setting step 304, a laser processing step 305, and a separation step 306.

### Holding Step

The holding step 301 is a step of holding the ingot 200 by the holding unit 10 to expose the first surface 201. In the first embodiment, in the holding step 301, processing conditions of the separation apparatus 1 are registered in the control unit 100 by the operator, and the second surface 202 of the ingot 200 is placed on the holding surface 11 of the holding unit 10. Note that the processing conditions include information indicating whether or not the first surface 201 of the ingot 200 is formed into a mirror surface by, for example, grinding processing on the first surface 201 with a grinder. In the first embodiment, in the holding step 301, when an instruction to start the processing operation from the operator is received, the control unit 100 of the separation apparatus 1 sucks and holds the second surface 202 of the ingot 200 on the holding surface 11 of the holding unit 10.

Thereafter, the separation apparatus 1 determines whether or not grinding processing is required for the first surface 201 of the ingot 200 sucked and held by the holding unit 10 by the control unit 100 (step 302). Specifically, the control unit 100 determines that grinding processing is required for the first surface 201 of the ingot 200 sucked and held by the holding unit 10 (step 302: Yes) in a case where the processing conditions include information indicating that the first surface 201 of the ingot 200 has not been formed into a mirror surface and the peeling layer 211 is to be formed in the ingot 200 for the first time, or in a case where the peeling layer 211 has been formed in the ingot 200 sucked and held by the holding unit 10, the wafer 220 has been peeled, and the peeling surface 212 has not been formed into a mirror surface. When the control unit 100 determines that the grinding processing is required for the first surface 201 of the ingot 200 sucked and held by the holding unit 10 (step 302: Yes), the separation apparatus 1 proceeds to the grinding step 303.

### Grinding Step

The grinding step 303 is a step of grinding the first surface 201 of the ingot 200 sucked and held on the holding surface 11 of the holding unit 10 by the grinding wheel 63. In the first embodiment, in the grinding step 303, the control unit 100 of the separation apparatus 1 controls the movement unit 30 and the Y-axis direction position changing unit 65 to position the holding unit 10 below the grinding wheel 63 of the grinding unit 60.

In the first embodiment, in the grinding step 303, the control unit 100 of the separation apparatus 1 supplies grinding water while rotating each of the spindle 62 of the grinding unit 60 and the holding unit 10 about the axis, and lowers the spindle 62 and the grinding wheel 63 by the grinding feed unit 64 to bring the abrasive members 67 into contact with the first surface 201 of the ingot 200 and close to the holding unit 10 at a predetermined feed speed, thereby performing the grinding processing on the first surface 201 of the ingot 200 with the abrasive members 67. In the first embodiment, in the grinding step 303, when the ingot 200 is subjected to the grinding processing so that the ingot 200 is thinned by a predetermined thickness, the control unit 100 of the separation apparatus 1 controls the grinding feed unit 64 to raise the grinding wheel 63 and the like, stops the rotation of the spindle 62 and the holding unit 10 and the supply of the grinding water, and ends the grinding step 303.

After the end of the grinding step 303, or when the control unit 100 determines that the grinding processing is not required for the first surface 201 of the ingot 200 sucked and held by the holding unit 10 (step 302: No), the separation apparatus 1 proceeds to the specific region setting step 304.

### Specific Region Setting Step

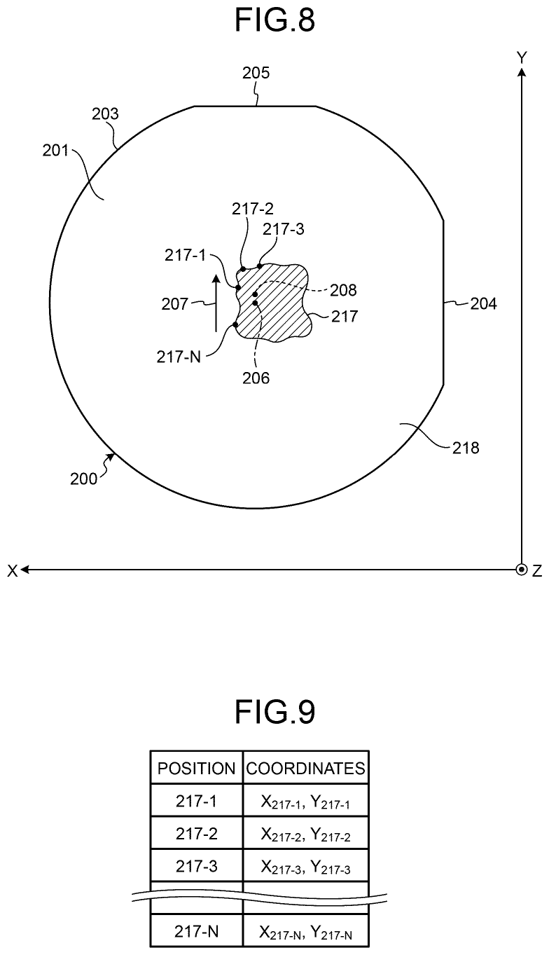

FIG. 7 is a perspective view schematically illustrating the specific region setting step of the separation method illustrated in FIG. 6. FIG. 8 is a plan view illustrating an example of a facet region of the SiC ingot illustrated in FIG. 7. FIG. 9 is a view illustrating an example of XY coordinates of an outer edge of the facet region illustrated in FIG. 8. The specific region setting step 304 is a step of setting the facet region 217 on the first surface 201 of the ingot 200 before or after the holding step 301.

In the first embodiment, in the specific region setting step 304, after the holding step 301, the control unit 100 of the separation apparatus 1 controls the movement unit 30 to move the holding unit 10 below the imaging unit 40, and causes the imaging unit 40 to capture an image of the ingot 200. In the first embodiment, in the specific region setting step 304, the control unit 100 of the separation apparatus 1 adjusts a direction around the axis of the holding unit 10 by the rotational movement unit 33 based on the image of the ingot 200 captured and acquired by the imaging unit 40, thereby making the second orientation flat 205 parallel to the X-axis direction, making a direction orthogonal to the inclination direction 207 parallel to the X-axis direction, and making the inclination direction 207 parallel to the Y-axis direction as illustrated in FIGS. 7 and 8.

In the first embodiment, in the specific region setting step 304, the control unit 100 of the separation apparatus 1 controls the movement unit 30 to irradiate the first surface 201 of the ingot 200 held on the holding surface 11 of the holding unit 10 with the inspection light 542 at predetermined intervals while relatively moving the facet region detection unit 50 and the holding unit 10 as illustrated in FIG. 7, and detect the luminance of the light 544 transmitted through the filter 57 out of the fluorescence 543 of the first surface 201 of the ingot 200 by the light receiving unit 58 at predetermined intervals. At this time, the inspection light 542 in the second wavelength range of the excitation light 541 oscillated from the light source 54 is reflected by the dichroic mirror 55, guided to the condensing lens 56, condensed by the condensing lens 56, and emitted to the first surface 201 of the ingot 200.

When the first surface 201 of the ingot 200 is irradiated with the inspection light 542, the ingot 200 generates the fluorescence 543 having a wavelength (for example, a wavelength of 750 nm or more) different from the wavelength of the inspection light 542, and the fluorescence 543 is emitted from the ingot 200. After the fluorescence 543 is reflected by the reflecting surface 591 of the elliptical mirror 59, only the light 544 in the first wavelength range is transmitted through the filter 57, the light 544 transmitted through the filter 57 is received by the light receiving unit 58, and the luminance of the light 544 is detected by the light receiving unit 58. The light receiving unit 58 outputs a signal corresponding to the luminance of the received light 544 to the control unit 100.

In the first embodiment, in the specific region setting step 304, the control unit 100 of the separation apparatus 1 alternately repeats irradiation of the inspection light 542 over the entire length of the ingot 200 in the X-axis direction while moving the holding unit 10 by the X-axis movement unit 31 in the X-axis direction and so-called indexing feed in which the holding unit 10 is moved in the Y-axis direction by a predetermined interval along the first orientation flat 204 until the luminance of the fluorescence 543 at the predetermined interval is detected over the entire first surface 201 of the ingot 200.

In the first embodiment, in the specific region setting step 304, the control unit 100 of the separation apparatus 1 calculates XY coordinates of a position irradiated with the inspection light 542 of the ingot 200 held by the holding unit 10 based on a position of the holding unit 10 detected by the respective position detection units and the like, and stores the calculated XY coordinates of the position irradiated with the inspection light 542 of the ingot 200 held by the holding unit 10 and the luminance of the light 544 in the storage device in association with each other.

In the first embodiment, in the specific region setting step 304, the control unit 100 of the separation apparatus 1 calculates of a region where the luminance of the light 544 is lower than a predetermined value among the XY coordinates of the position irradiated with the inspection light 542 of the ingot 200 held by the holding unit 10 stored in the storage device and the luminance of the light 544, that is, XY coordinates (X₂₁₇₋₁, Y₂₁₇₋₁), (X₂₁₇₋₂, Y₂₁₇₋₂), (X₂₁₇₋₃, Y₂₁₇₋₃), . . . , and (X_{217-N}, Y_{217-N}) of positions 217-1, 217-2, 217-3, . . . , and 217-N illustrated in FIG. 8 of the outer edge of the facet region 217 as illustrated in FIG. 9, for example.

Note that positions 217-1, 217-2, 217-3, . . . , and 217-N illustrated in FIG. 9 are the positions 217-1, 217-2, 217-3, . . . , and 217-N illustrated in FIG. 8. For example, as illustrated in FIG. 9, the control unit 100 temporarily stores the calculated XY coordinates (X₂₁₇₋₁, Y₂₁₇₋₁), (X₂₁₇₋₂/Y₂₁₇₋₂), (X₂₁₇₋₃, Y₂₁₇₋₃), . . . , and (X_{217-N}, Y_{217-N}) of the respective positions 217-1, 217-2, 217-3, . . . , and 217-N of the outer edge of the facet region 217 in the storage device, and sets a position of the facet region 217 on the first surface 201 of the ingot 200. Thus, in an eleventh embodiment, the facet region 217 is set based on optical identification of the ingot 200 by setting the facet region 217 based on the luminance of the light 544 in the specific region setting step 304.

### Laser Processing Step

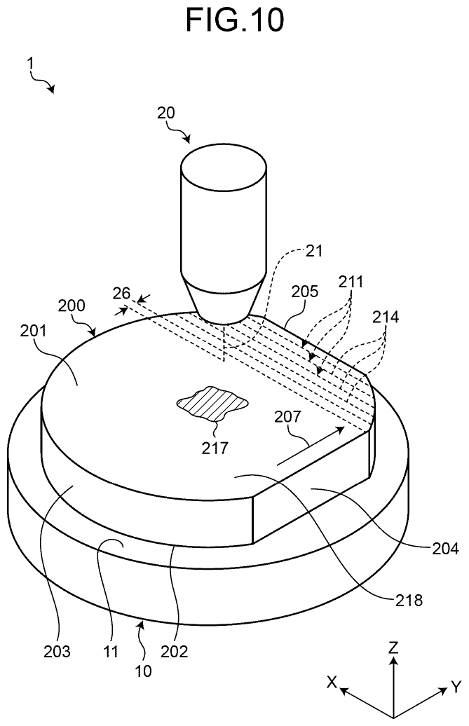

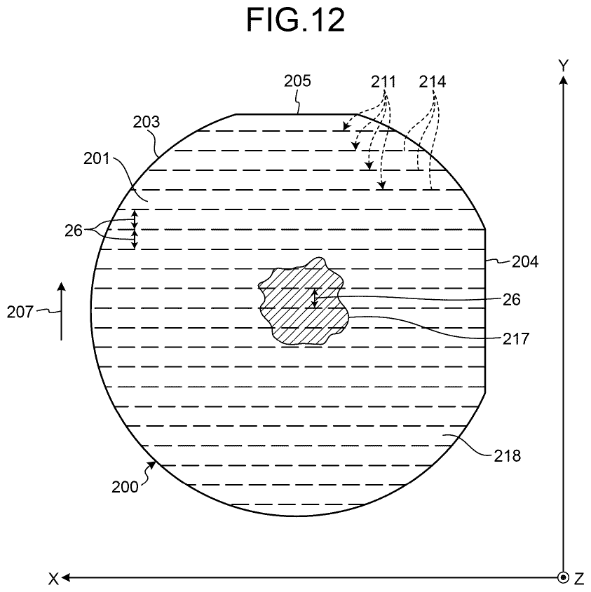

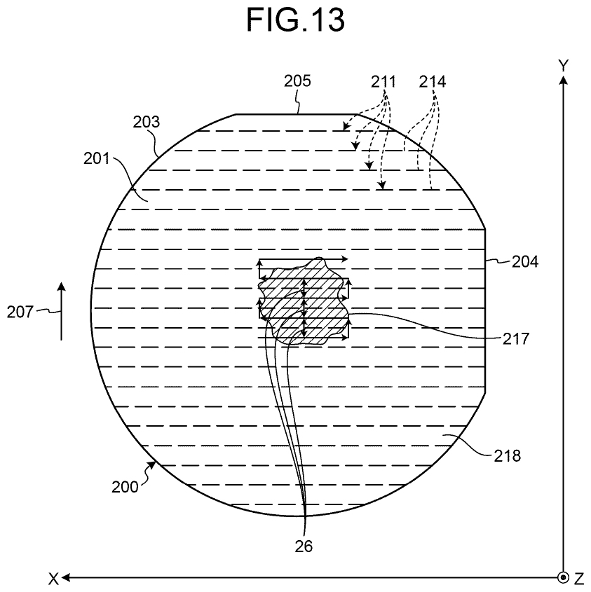

FIG. 10 is a perspective view schematically illustrating the laser processing step of the separation method illustrated in FIG. 6. FIG. 11 is a cross-sectional view schematically illustrating a surface layer of a first surface of an ingot illustrated in FIG. 10 on which a peeling layer is formed. FIG. 12 is a plan view schematically illustrating the ingot after a first sub-step of the laser processing step illustrated in FIG. 10. FIG. 13 is a plan view schematically illustrating a path of laser beam irradiation in a second sub-step of the laser processing step illustrated in FIG. 10.

After the holding step 301 and the specific region setting step 304 are performed, the laser processing step 305 is a step of repeating the processing feed in which the modified portion 214 having a strip shape is formed inside the ingot 200 by relatively moving a condensing point of the laser beam 21 in the X-axis direction, which is the processing feed direction with respect to the ingot 200, while irradiating the first surface 201 with the laser beam 21 in a state where the condensing point of the laser beam 21 is positioned inside the ingot 200 and the indexing feed in which the condensing point is relatively moved in the Y-axis direction which is the indexing feed direction orthogonal to the X-axis direction with respect to the ingot 200 after the processing feed, thereby forming a plurality of the modified portions 214 inside the ingot 200 and forming the peeling layer 211 which is a separation start point including the plurality of modified portions 214 inside the ingot 200.

In the first embodiment, the laser processing step 305 includes a first sub-step 3051 and a second sub-step 3052 as illustrated in FIG. 6. The first sub-step 3051 is a step of repeating relative movement of the condensing point while emitting the laser beam 21 from one end to the other end of the outer peripheral edge of the ingot 200 in the X-axis direction, and then relative movement of the condensing point in the Y-axis direction.

In the first embodiment, in the first sub-step 3051, the control unit 100 of the separation apparatus 1 adjusts relative positions of the ingot 200 and the concentrator of the laser processing unit 20 to cause an outer edge portion of the ingot 200 closer to the second orientation flat 205 and the concentrator 23 to face each other along the Z-axis direction in the first embodiment. In the first embodiment, in the first sub-step 3051, the control unit 100 of the separation apparatus 1 adjusts a position of the concentrator in the Z-axis direction by the condensing point movement unit, and positions the condensing point of the laser beam 21 at a depth corresponding to the thickness 222 of the wafer 220 to be generated from the first surface 201 of the ingot 200.

In the first embodiment, in the first sub-step 3051, the control unit 100 of the separation apparatus 1 irradiates the ingot 200 with the laser beam 21 having a wavelength having transmissibility with respect to SiC by the concentrator while performing the processing feed of the holding unit 10 at a predetermined processing feed rate by the X-axis movement unit 31 along the X-axis direction, that is, along the second orientation flat 205 as illustrated in FIG. 10.

In the ingot 200, by the irradiation with the laser beam 21, the peeling layer 211 including the modified portion 214 in which SiC is separated into Si (silicon) and C (carbon), the pulsed laser beam 21 to be irradiated next is absorbed by the previously formed C, and SiC is sequentially separated into Si and C, and the crack 215 extending from the modified portion 214 along the c-plane 209 is formed as illustrated in FIG. 11.

In the first embodiment, in the first sub-step 3051, when the control unit 100 of the separation apparatus 1 forms the peeling layer 211 over the entire length in the X-axis direction of the outer edge portion of the ingot 200 closer to the second orientation flat 205, the Y-axis movement unit 32 performs movement (hereinafter, referred to as indexing feed) of the holding unit 10 in the Y-axis direction along the first orientation flat 204 by a predetermined movement distance 26 in a direction in which the concentrator 23 of the laser processing unit 20 faces the center of the first surface 201 of the ingot 200.

In the first embodiment, in the first sub-step 3051, the control unit 100 of the separation apparatus 1 repeats the irradiation with the laser beam 21 while moving the holding unit 10 in the X-axis direction by the X-axis movement unit 31 and the indexing feed alternately until the peeling layer 211 is formed on the entire lower side of the first surface 201.

As a result, as illustrated in FIGS. 11 and 12, in the ingot 200, the peeling layer 211 having a lower strength than other portions including the modified portion 214 in which SiC is separated into Si and C and the crack 215 is formed at the depth corresponding to the thickness 222 of the wafer 220 from the first surface 201 for each movement distance 26 of the indexing feed. In the ingot 200, the peeling layer 211 is formed at the depth corresponding to the thickness 222 of the wafer 220 from the first surface 201 for each movement distance of the indexing feed over the entire length in a direction parallel to the first orientation flat 204.

The second sub-step 3052 is a step of repeating relative movement of the condensing point while emitting the laser beam 21 from one end to the other end of the facet region 217 in the X-axis direction, and then relative movement of the condensing point in the Y-axis direction before or after the first sub-step 3051. In the first embodiment, in the second sub-step 3052, the control unit 100 of the separation apparatus 1 adjusts the relative positions of the ingot 200 and the concentrator of the laser processing unit 20 based on the XY coordinates (X₂₁₇₋₁, Y₂₁₇₋₁), (X₂₁₇₋₂, Y₂₁₇₋₂), (X₂₁₇₋₃, Y₂₁₇₋₃), . . . , and (X_{217-N}, Y_{217-N}) of the respective positions 217-1, 217-2, 217-3, . . . , and 217-N of the outer edge of the facet region 217 stored in the storage device, and causes the center between the peeling layers 211, adjacent to each other in the Y-axis direction on an outer edge portion of the facet region 217 of the ingot 200 on the side away from the second orientation flat 205, and the concentrator 23 face each other in the Z-axis direction.

In the first embodiment, in the second sub-step 3052, the control unit 100 of the separation apparatus 1 irradiates the ingot 200 with the laser beam 21 having a wavelength having transmissibility with respect to SiC by the concentrator while performing the processing feed of the holding unit 10 at a predetermined processing feed rate by the X-axis movement unit 31 along the X-axis direction, that is, along the second orientation flat 205, thereby forming the peeling layer 211 over the entire length in the X-axis direction of the facet region 217.

In the first embodiment, in the first sub-step 3051, when the control unit 100 of the separation apparatus 1 forms the peeling layer 211 over the entire length in the X-axis direction of the outer edge portion of the facet region 217 of the ingot 200 on the side away from the second orientation flat 205, the Y-axis movement unit 32 performs movement (hereinafter, referred to as indexing feed) of the holding unit 10 in the Y-axis direction along the first orientation flat 204 by a predetermined movement distance 26 in a direction in which the concentrator of the laser processing unit 20 faces the center of the first surface 201 of the ingot 200.

In the first embodiment, in the second sub-step 3052, as illustrated in FIG. 13, the control unit 100 of the separation apparatus 1 repeats the irradiation with the laser beam 21 by the X-axis movement unit 31 while moving the holding unit 10 in the X-axis direction and the indexing feed alternately until the peeling layer 211 is formed at the center in the Y-axis direction of the peeling layer 211 formed in the first sub-step 3051 over the entire region below the first surface 201 of the facet region 217. Thus, in the first embodiment, in the laser processing step 305, the predetermined movement distance 26 (corresponding to the interval) for the indexing feed in the first sub-step 3051 and the predetermined movement distance 26 (corresponding to the interval) for the indexing feed in the second sub-step 3052 are made equal in the first embodiment.

Thus, in the first embodiment, in the second sub-step 3052 of the laser processing step 305, the peeling layer 211 is formed at the center in the Y-axis direction of the peeling layer 211 formed in the first sub-step 3051, so that the ingot 200 is irradiated with the laser beam 21 at different positions in the Y-axis direction between the first sub-step 3051 and the second sub-step 3052. In addition, in the first embodiment, since the peeling layer 211 is formed at the center in the Y-axis direction of the peeling layer 211, formed in the first sub-step 3051, in the second sub-step 3052 of the laser processing step 305, an interval between the modified portions 214 adjacent in the Y-axis direction in the facet region 217 is set to be narrower than an interval between the modified portions 214 adjacent in the Y-axis direction in the non-facet region 218 outside the facet region 217.

In addition, in the first embodiment, since the predetermined movement distance 26 for the indexing feed in the first sub-step 3051 and the predetermined movement distance 26 for the indexing feed in the second sub-step 3052 are made equal in the laser processing step 305, the condensing point is relatively moved in the indexing feed direction by the same indexing amount in the first sub-step 3051 and the second sub-step 3052.

In addition, the processing conditions such as an output, a repetition frequency, and the processing feed rate of the laser beam 21 in the first sub-step 3051 and the second sub-step 3052 are made equal in the laser processing step 305 in the first embodiment, but may be made different in the present disclosure. In addition, in the laser processing step 305, the depth of the condensing point of the laser beam 21 is made equal in the first sub-step 3051 and the second sub-step 3052 are made equal, but may be made different in the present disclosure. In this case, the laser beam 21 may be emitted by setting the depth of the condensing point in the second sub-step 3052 to be shallower than that in the first sub-step 3051, that is, changing the position of the condensing point closer to the condensing lens side.

### Separation Step

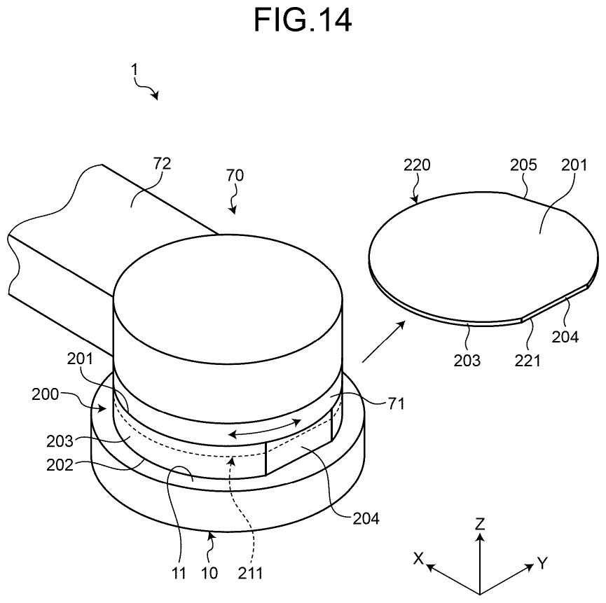

FIG. 14 is a perspective view schematically illustrating the separation step of the separation method illustrated in FIG. 6. The separation step 306 is a step of separating the ingot 200 from the peeling layer 211 into the first surface 201 side and the second surface 202 side after the laser processing step 305 is performed.

In the first embodiment, in the separation step 306, the control unit 100 of the separation apparatus 1 controls the movement unit 30 to position the holding unit 10 below the holding plate 71 of the separation unit 70. In the first embodiment, in the separation step 306, the control unit 100 of the separation apparatus 1 controls the separation unit 70 to lower the holding plate 71 and cause the holding plate 71 to suck and hold the first surface 201 of the ingot 200.

In the first embodiment, in the separation step 306, the control unit 100 of the separation apparatus 1 controls the separation unit 70 to cause the ultrasonic vibration applying unit to apply an ultrasonic wave to the holding plate 71 for a predetermined time as illustrated in FIG. 14. Then, the ingot 200 is broken with the peeling layer 211 as a start point. In the first embodiment, in the separation step 306, the control unit 100 of the separation apparatus 1 controls the separation unit 70 to raise the holding plate 71, and separates and peels a portion, that is, the wafer 220 to be generated from the ingot 200, that is, separates the ingot 200 into the first surface 201 side and the second surface 202 side.

Note that the holding step 301, the specific region setting step 304, and the laser processing step 305 of the separation method described above constitute a separation start point forming method of forming, inside the ingot 200, the peeling layer 211 for separating the ingot 200 having the first surface 201 and the second surface 202 at the back of the first surface 201 into the first surface 201 side and the second surface 202 side.

In general, since the facet region 217 has a higher energy absorption rate than the non-facet region 218, the energy intensity at the condensing point is lower than that of the non-facet region 218. Therefore, in the facet region 217, the number of the cracks 215 extending from the modified portions 214 to be formed along the c-plane 209 is smaller than that in the non-facet region 218, the amount of extension of the crack 215 is also shortened, so that there is a possibility that peeling failure occurs as the cracks 215 are not connected between the adjacent peeling layers 211. Therefore, in the separation start point forming method and the separation method according to the first embodiment, the interval between the modified portions 214 adjacent in the Y-axis direction in the facet region 217 is set to be narrower than the interval between the modified portions 214 adjacent in the Y-axis direction in the non-facet region 218 outside the facet region 217, and thus, it is possible to suppress the possibility of occurrence of separation failure of the facet region 217.

As a result, the separation start point forming method and the separation method according to the first embodiment have an effect of suppressing separation failure of the ingot 200.

### First Modification

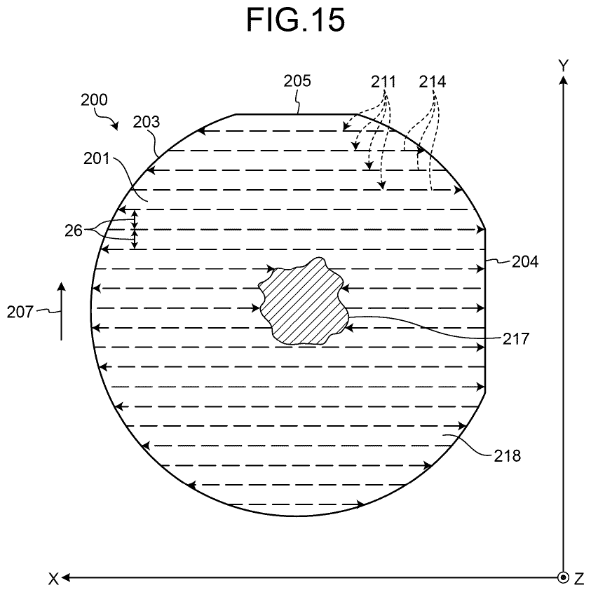

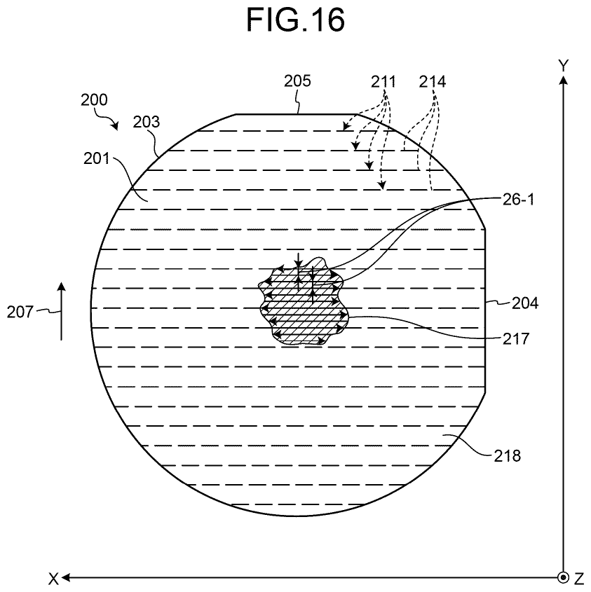

A separation start point forming method and a separation method according to a first modification of the first embodiment will be described with reference to the drawings. FIG. 15 is a plan view schematically illustrating an ingot after a first sub-step of a laser processing step of the separation start point forming method and the separation method according to the first modification of the first embodiment. FIG. 16 is a plan view schematically illustrating a path of laser beam irradiation in a second sub-step of the laser processing step of the separation start point forming method and the separation method according to the first modification of the first embodiment. Note that, in FIGS. 15 and 16, the same portions as those in the first embodiment are denoted by the same reference signs, and the description thereof is omitted.

The separation start point forming method and the separation method according to the first modification are the same as those of the first embodiment except that the peeling layer 211 is formed only in the non-facet region 218 as illustrated in FIG. 15 in the first sub-step 3051 of the laser processing step 305, the peeling layer 211 is formed only in the facet region 217 as illustrated in FIG. 16 in the second sub-step 3052, and a predetermined movement distance 26-1 for indexing feed in the second sub-step 3052 is narrower than the predetermined movement distance 26 for indexing feed in the first sub-step 3051.

In the first modification, in the first sub-step 3051 of the laser processing step 305, similarly to the first embodiment, the control unit 100 of the separation apparatus 1 repeats irradiation with the laser beam 21 while moving the holding unit 10 in the X-axis direction by the X-axis movement unit 31 and the indexing feed alternately until the peeling layer 211 is formed over the entire lower portion of the first surface 201, and stops the irradiation with the laser beam 21 on the facet region 217 based on the XY coordinates (X₂₁₇₋₁, Y₂₁₇₋₁), (X₂₁₇₋₂, Y₂₁₇₋₂), (X₂₁₇₋₃, Y₂₁₇₋₃), . . . , and (X_{217-N}, Y_{217-N}) of the respective positions 217-1, 217-2, 217-3, . . . , and 217-N of the outer edge of the facet region 217 stored in the storage device.

In the first modification, in the first sub-step 3051 of the laser processing step 305, similarly to the first embodiment, the irradiation with the laser beam 21 by the X-axis movement unit 31 while moving the holding unit 10 in the X-axis direction and the indexing feed are alternately repeated until the peeling layer 211 is formed on the entire lower side of the first surface 201 of the facet region 217, and the predetermined movement distance 26-1 for the indexing feed in the second sub-step 3052 is narrower than the predetermined movement distance 26 for the indexing feed in the first sub-step 3051.

In the separation start point forming method and the separation method according to the first modification, the ingot 200 is irradiated with the laser beam 21 at different positions in the Y-axis direction in the first sub-step 3051 and the second sub-step 3052 since the predetermined movement distance 26-1 for the indexing feed in the second sub-step 3052 is narrower than the predetermined movement distance 26 for the indexing feed in the first sub-step 3051. In addition, in the separation start point forming method and the separation method according to the first modification, an interval between the modified portions 214 adjacent in the Y-axis direction in the facet region 217 is set to be narrower than an interval between the modified portions 214 adjacent in the Y-axis direction in the non-facet region 218 outside the facet region 217 since the predetermined movement distance 26-1 for the indexing feed in the second sub-step 3052 is narrower than the predetermined movement distance 26 for the indexing feed in the first sub-step 3051.

In the separation start point forming method and the separation method according to the first modification, similarly to the first embodiment, it is possible to suppress the possibility of occurrence of separation failure of the facet region 217 and to suppress separation failure of the ingot 200 since the interval between the modified portions 214 adjacent in the Y-axis direction in the facet region 217 is set to be narrower than the interval between the modified portions 214 adjacent in the Y-axis direction in the non-facet region 218 outside the facet region 217.

### Second Modification

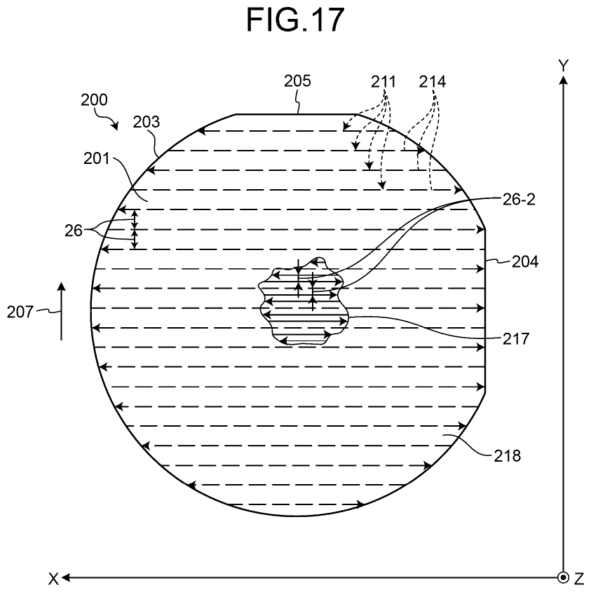

A separation start point forming method and a separation method according to a second modification of the first embodiment will be described with reference to the drawings. FIG. 17 is a plan view schematically illustrating a path of laser beam irradiation in a first sub-step and a second sub-step of a laser processing step of the separation start point forming method and the separation method according to the second modification of the first embodiment. Note that, in FIG. 17, the same portions as those in the first embodiment are denoted by the same reference signs, and the description thereof is omitted.

As illustrated in FIG. 17, the separation start point forming method and the separation method according to the second modification are the same as those of the first embodiment except that, in the laser processing step 305, the second sub-step 3052 is performed during the first sub-step 3051, and a predetermined movement distance 26-2 for indexing feed in the second sub-step 3052 is narrower than the predetermined movement distance 26 for indexing feed in the first sub-step 3051.

In the first modification, in the laser processing step 305, similarly to the first embodiment, when the control unit 100 of the separation apparatus 1 repeats irradiation with the laser beam 21 while moving the holding unit 10 in the X-axis direction by the X-axis movement unit 31 and the indexing feed alternately until the peeling layer 211 is formed over the entire lower portion of the first surface 201, the predetermined movement distance 26-2 for the indexing feed in the second sub-step 3052 on the facet region 217 is set to be narrower than the predetermined movement distance 26 for the indexing feed in the first sub-step 3051 based on the XY coordinates (X₂₁₇₋₁, Y₂₁₇₋₁), (X₂₁₇₋₂, Y₂₁₇₋₂), (X₂₁₇₋₃, Y₂₁₇₋₃), . . . , and (X_{217-N}, Y_{217-N}) of the respective positions 217-1, 217-2, 217-3, . . . , and 217-N of the outer edge of the facet region 217 stored in the storage device.

In the separation start point forming method and the separation method according to the second modification, the ingot 200 is irradiated with the laser beam 21 at different positions in the Y-axis direction in the first sub-step 3051 and the second sub-step 3052 since the predetermined movement distance 26-2 for the indexing feed in the second sub-step 3052 is narrower than the predetermined movement distance 26 for the indexing feed in the first sub-step 3051. In addition, in the separation start point forming method and the separation method according to the second modification, an interval between the modified portions 214 adjacent in the Y-axis direction in the facet region 217 is set to be narrower than an interval between the modified portions 214 adjacent in the Y-axis direction in the non-facet region 218 outside the facet region 217 since the predetermined movement distance 26-2 for the indexing feed in the second sub-step 3052 is narrower than the predetermined movement distance 26 for the indexing feed in the first sub-step 3051.

In the separation start point forming method and the separation method according to the second modification, similarly to the first embodiment, it is possible to suppress the possibility of occurrence of separation failure of the facet region 217 and to suppress separation failure of the ingot 200 since the interval between the modified portions 214 adjacent in the Y-axis direction in the facet region 217 is set to be narrower than the interval between the modified portions 214 adjacent in the Y-axis direction in the non-facet region 218 outside the facet region 217.

The second sub-step 3052 is performed after the first sub-step 3051 in the laser processing step 305 in the first embodiment and the first modification, but the first sub-step 3051 may be performed after the second sub-step 3052 in the present disclosure. In addition, the specific region setting step 304 may be performed before the holding step 301 in the present disclosure. In addition, in the present disclosure, a workpiece is not limited to the ingot 200 described above, and may be, for example, the wafer 220 illustrated in FIG. 4 separated from the ingot 200.

According to the present disclosure, it is possible to suppress separation failure.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A separation start point forming method of forming, inside a workpiece that has a first surface and a second surface at a back of the first surface, a separation start point for separating the workpiece into the first surface side and the second surface side, the separation start point forming method comprising:
holding the workpiece by a holding unit to expose the first surface;
setting a specific region on the first surface of the workpiece before or after the holding; and
after the holding and the setting, repeating processing feed and indexing feed to form a plurality of modified portions inside the workpiece and form a separation start point including the plurality of modified portions inside the workpiece, the processing feed being of relatively moving a condensing point of a laser beam in a processing feed direction with respect to the workpiece while emitting the laser beam toward the first surface with the condensing point positioned inside the workpiece to form a strip-shaped modified portion inside the workpiece, the indexing feed being of relatively moving the condensing point in an indexing feed direction, orthogonal to the processing feed direction, with respect to the workpiece after the processing feed, wherein
in the repeating, an interval between the modified portions adjacent to each other in the specific region is set to be narrower than an interval between the modified portions adjacent to each other outside the specific region.

2. The separation start point forming method according to claim 1, wherein
the repeating includes:
a first sub-step of repeating relative movement of the condensing point while emitting the laser beam from one end to another end of an outer peripheral edge of the workpiece in the processing feed direction and then relative movement of the condensing point in the indexing feed direction; and
a second sub-step of repeating, before or after the first sub-step, relative movement of the condensing point while emitting the laser beam from one end to another end of the specific region in the processing feed direction and then relative movement of the condensing point in the indexing feed direction, and
the laser beam is emitted in the indexing feed direction to different positions in the first sub-step and the second sub-step.

3. The separation start point forming method according to claim 2, wherein the condensing point is relatively moved in the indexing feed direction by an equal indexing amount in the first sub-step and the second sub-step.

4. The separation start point forming method according to claim 1, wherein the setting includes setting the specific region based on an optical characteristic of the workpiece.

5. A separation method of separating a workpiece that has a first surface and a second surface at a back of the first surface into the first surface side and the second surface side, the separation method comprising:
holding the workpiece by a holding unit to expose the first surface;
setting a specific region on the first surface of the workpiece before or after the holding;
after the holding and the setting, repeating processing feed and indexing feed to form a plurality of modified portions inside the workpiece and form a separation start point including the plurality of modified portions inside the workpiece, the processing feed being of relatively moving a condensing point of a laser beam in a processing feed direction with respect to the workpiece while emitting the laser beam toward the first surface with the condensing point positioned inside the workpiece to form a strip-shaped modified portion inside the workpiece, the indexing feed being of relatively moving the condensing point in an indexing feed direction, orthogonal to the processing feed direction, with respect to the workpiece after the processing feed; and
after the repeating, separating the workpiece from the separation start point into the first surface side and the second surface side, wherein
in the repeating, an interval between the modified portions adjacent to each other in the specific region is set to be narrower than an interval between the modified portions adjacent to each other outside the specific region.
